(19) United States
(12) Patent Application Publication
(10) Pub. No.: US 2024/0234624 A1
(43) Pub. Date: Jul. 11, 2024

(54) INTEGRATED COLOR CONVERSION CARTRIDGE

(71) Applicant: VueReal Inc., Waterloo (CA)

(72) Inventors: Gholamreza Chaji, Waterloo (CA); Ehsanollah Fathi, Waterloo (CA)

(73) Assignee: VueReal Inc., Waterloo, ON (CA)

(21) Appl. No.: 18/558,867

(22) PCT Filed: May 4, 2022
(86) PCT No.: PCT/CA2022/050696

§ 371 Date: Nov. 3, 2023

Related U.S. Application Data
(60) Provisional application No. 63/183,760, filed on May 4, 2021.

(51) Int. Cl. H01L 33/00

(52) U.S. Cl. CPC H01L 33/0095; H01L 2933/0041; H01L 2933/005; H01L 2933/0058

(57) ABSTRACT

The present invention discloses development of microdevices with an optical structure on a substrate. In particular it discloses aspects of microdevices having sidewalls, top and bottom sides, and methods to create a housing or cavity using different processes. The processes use protection layers, patterning, and passivation as well as alignment techniques.

### FIELD OF THE INVENTION

The present disclosure relates to the integration of microdevices into a system substrate.

### BRIEF SUMMARY

According to one embodiment the invention method of developing microdevices with an optical structure on a substrate, the method comprising, holding the microdevice on top of the substrate wherein microdevice has a top side, a bottom side and side walls that are different from the bottom side and the top side and the top side faces away from the substrate, forming optical layers on the top side of microdevices, forming a passivation layer on top of optical layers, and transferring microdevices and the optical layers into a system substrate.

According to another embodiment the invention discloses a method of developing microdevices with an optical structure on a substrate, the method comprising, holding the microdevices on a first bonding layer on top of the substrate, covering the microdevices with the first layer, covering the microdevices with a protection layer, forming optical layers on top of the first bonding layer aligned with the microdevice, and forming a passivation layer on top of the optical layers such that the passivation layer covers sidewalls of the microdevices as well.

According to another embodiment, the invention discloses a method of integrating a microdevice with an optical structure, the method comprising, covering the microdevice with a protection layer, extending a part of the protection layer to create a housing, and holding an optical layer in the housing.

### BRIEF DESCRIPTION OF THE DRAWINGS

The foregoing and other advantages of the disclosure will become apparent upon reading the following detailed description and upon reference to the drawings.

FIG. 1A shows one method of developing the microdevice with an optical structure on a donor substrate

FIG. 1B shows the devices are etched back to create a housing structure.

FIG. 1C shows the release layer is patterned.

FIG. 1D shows, after the layers are formed on top of the optical structure a substrate is bonded to the top surface using a bonding layer.

FIG. 1E shows that the temporary substrate can be removed.

FIGS. 2A and 2B show another related embodiment where there is no layer between the devices.

FIG. 2C shows a release layer is formed under the devices.

FIG. 2D shows an anchor layer is also formed under the device and the release layer.

FIG. 3A shows an exemplary embodiment of microdevices developed with an optical layer integrated in the device.

FIG. 3B shows an example of integrating the device of FIG. 3A into a receiver backplane.

FIG. 3C shows an example of integrating the device of FIG. 3A into a receiver backplane.

The present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

The following description describes methods of integration and structure of microdevices developing and/or integrating with an optical structure. There is no additional need or describing method aspects separately and the description can be construed to be equivalent to a method wherein description of structure, material detail and various processes is combinedly used to claim a method.

A microdevice on a donor substrate has a top face away from the substrate and down bottom facing the substrate. At least part of the top or bottom face of the microdevice is covered by an optical layer (e.g., color conversion material, or lens, etc.). A layer holding the bottom side of the microdevice to the donor substrate. The layer can be an adhesive or anchors. There can be a release layer between the holding layer and the substrate. There can be a light coupling or an encapsulation layer between the device and the optical layer. There can be a protection layer covering at least one other side of the device that is not covered by the color conversion layer. The protection layer can be extended on the edge of the surface covered by the optical layer to house at least part of the optical layer. The protection layer can be reflective to direct the light toward the optical layer. In one related case, the devices in the donor substrate can have more than one type of optical layer. In another related case, the different devices can have different optical layers. For example, one device can have green color conversion layers and the other one red color conversion layers. The devices are transferred into a receiver substrate to form an array of microdevices. The optical layer can create different functionality in the devices such as color conversion or directing the input or output light to a specific direction or modifying the light profiles. The microdevices can have pads on either top or bottom side or other sides that are not top or bottom sides. The pads provide electrical connections to the device. And the substrate is coupled to the devices through the pads. The microdevices may have several layers such as p-layer, n-layer, blocking layers, buffer layers, ohmic layers, and active layers. The active layers can be multi-quantum well (MQW).

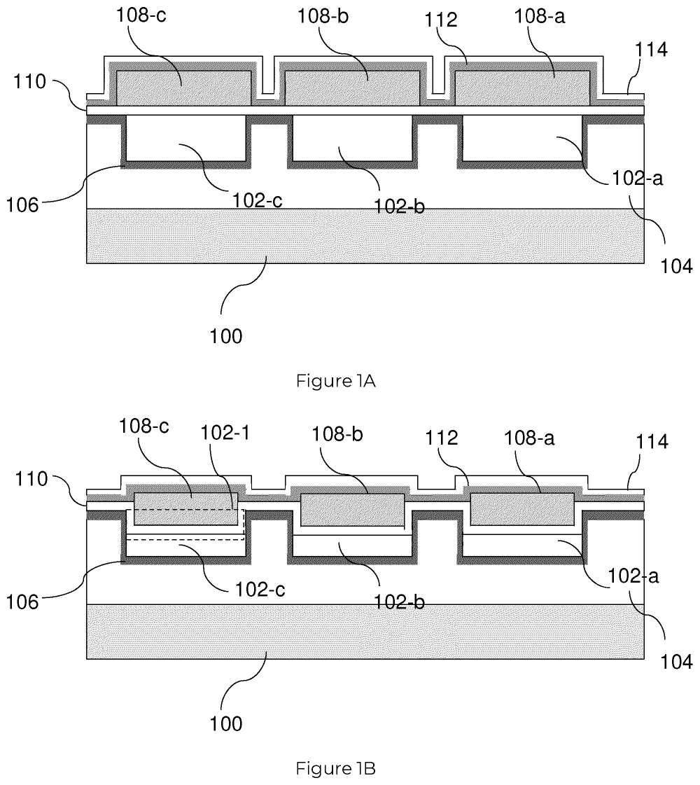

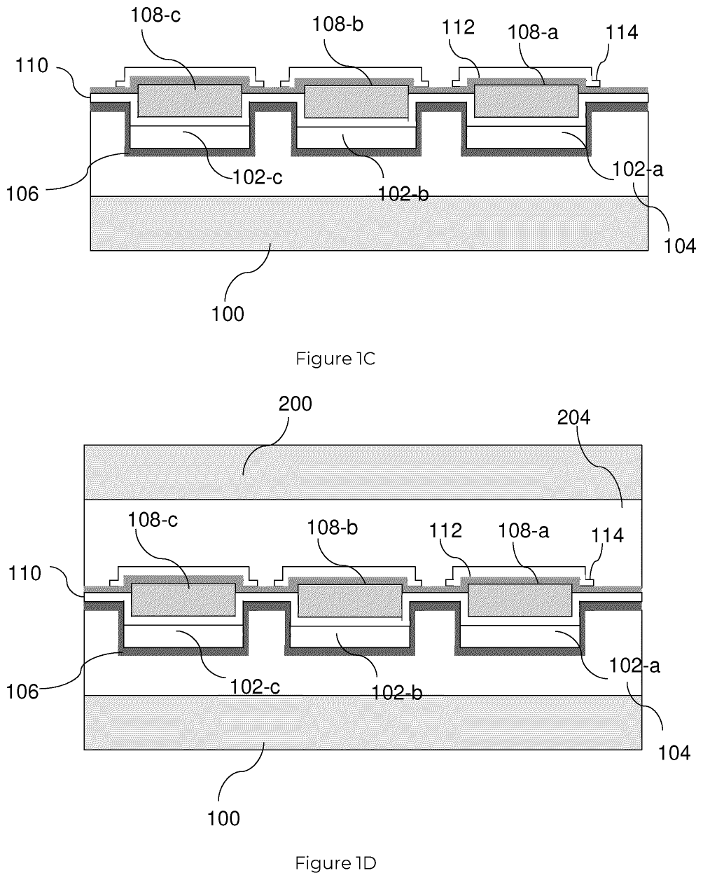

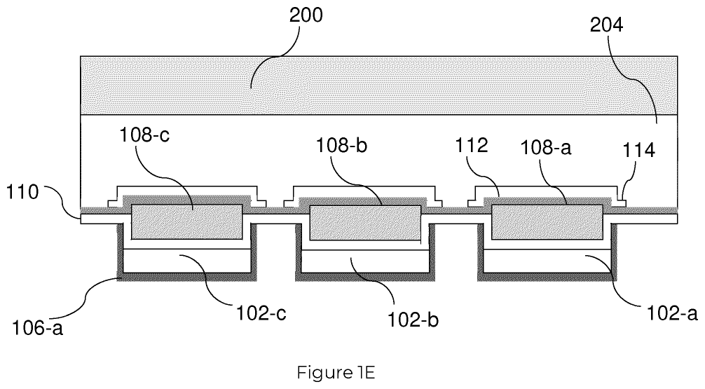

FIG. 1A shows one method of developing the microdevice with an optical structure on a donor substrate. The method includes microdevices 102a, 102b and 102c (from hereon: 102 a, b, c.) holding on a substrate 100 with a layer 104. The layer 104 can be polymers such as BCB, Polyamide, SU8 or other types. The layer can also cover the devices 102 a, b, c. There can be a protection layer(s) 106. Part of the protection layer 106 can cover the device. There can be stacks of reflective layers, dielectric layers, and stop layers. The devices 102 a, b, c can be transferred from another substrate to donor/temporary substrate 100. Or the devices 102 a, b, c can be formed on the substrate 100. A passivation layer, anchor or optical layer 110 can be formed on at least part of the devices. The layer 110 can also be extended and patterned outside the devices 102 a, b, c. The layer 110 can form anchors or bridge to hold the device in place and release the device during transferring the device into a system substrate. Optical layer 108 a, b, c can be formed and aligned with the devices 102 a, b, c. There can be more than one type of optical layer for each device 102 a, b, c tailoring the functionality of each device. In one case, the optical layer 108 a, b, c can be a color conversion layer. In another related case, the optical layer 108 a, b, c can be a lens structure. Alternatively, the optical layer 108 a, b, c also can be a combination of lens and a color conversion layer or a color filter layer. In one case, different optical layers are formed by patterning. For example, layer 108a is formed and patterned on top of device 102a. Then the next layer 108b is formed and patterned on top of 102b. It can continue till all desired layers are formed. In another case, the layers can be printed or stamped. Other methods also can be used to form the optical layers. After the optical layers are formed, a passivation layer 112 can form on top of the device. The passivation layer 112 can also include an anchor layer. In the case of an anchor layer, the anchor layer is patterned outside the devices 102 a, b, c. In one related case, a release layer 114 is formed. Here the release layer is patterned and aligned with the optical layers 108 a, b, c and device layers 102 a, b, c.

In another related case, as shown in FIG. 1B, the devices 102 a, b, c, are etched back to create a housing structure 102-1 for at least part of the optical layer 108a, 108b, 108c (from hereon: 108 a, b, c). Part of the optical layers 108 a, b, c is formed inside the housing structure 102-1. Other layers as described previously can be formed after the optical layers 108 a, b, c in the housing structure 102-1. In one method, the devices 102 a, b, c are formed (or transferred to) substrate. The sidewalls of devices are covered with different housing layers 102-1. The layers 102-1 can include dielectrics and or reflective layers. After this process, the top or bottom surface of the device is etched back to expose sidewalls forming a housing cavity on top or bottom surface. The optical layer is formed on the top or bottom surface and at a least part of the optical layer is inside the housing cavity formed by the housing layers 102-1. There can be other layers before or after the optical layer. In another related method, the etch back process can include patterning and leave some of the device materials on the sidewalls and only etch back the inner part of top or bottom surfaces. Therefore, the remaining layers form the housing layers 102-1 or be part of the housing layers 102-1. The etch back process can be done by wet etching or dry etching process. The housing layers can be formed by different deposition processes such as PECVD, ALD, spin coating, printing, or other related methods. The process described in FIG. 1B can be used to form and fabricate other related devices and methods described here.

The release layer 114 can be patterned as demonstrated in FIG. 1C. Here, the device can be transferred from the substrate 100 to a system (receiver) substrate. In this case, the protective layer 106 can include a release layer that can be removed to the detached part of microdevices 102 a, b, c from the layer 104. The transfer can be done directly by bringing the donor substrate 100 to a receiver substrate, aligning it. Here, the devices can be bonded to the receiver substrate and left there either by mechanical or laser release. In another related case, the microdevices can be picked from the donor substrate 100 and transferred to the receiver substrate.

In another related case, as shown in FIG. 1D, after the layers are formed on top of the optical structure 108 a, b, c, a substrate 200 is bonded to the top surface using bonding layer 204. The bonding layer 204 can be polymer or other types of adhesive materials. Here the substrate 100 is a temporary substrate that can be removed (FIG. 1E). Also, the bonding layers 104 can be removed exposing the original bottom surface of the device 102 a, b, c. Here, the surfaces are swapped as per definition. Some of the protective layers can be removed or patterned. In one related case, part of the protective layers 106 cover some surface of the device not covered by the optical structure. The remaining proactive layers 106 can be reflective. Layers 110 or 112 can be patterned to form anchors. In another case, one of the layers 110 or 112 or 204 can also be a temporary adhesive that releases the devices under different conditions. Here, the release layer 114 can be removed. The substrate can be bonded selectively to the receiver substrate and devices are released to the receiver substrate. In another case, a laser is used to release the layer 112 and transfer the device to the receiver substrate.

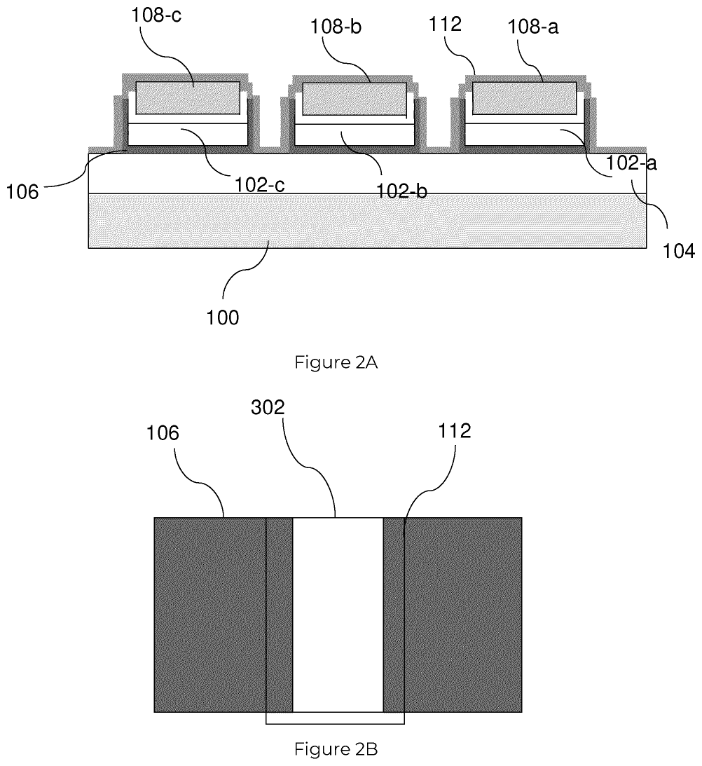

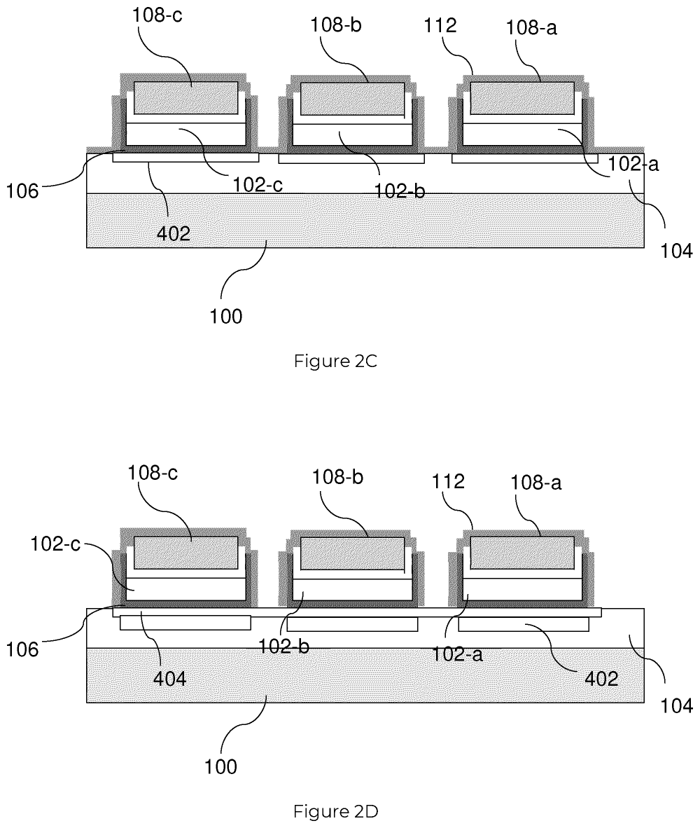

FIGS. 2A and 2B show another related embodiment. Here, there is no layer between the devices 102 a, b, c. The layer 112 covers the sidewalls of the device as well. Here the layer 106 or 104 can be a temporary adhesive that releases the device under some conditions (e.g., temperature, light or etc.). In another related case, layer 106 can be a release layer. It is patterned so that the layer 112 connects to the device wall. FIG. 2B shows an exemplary pattern. The layer 106 is removed in pattern 302. The layer 112 after deposition can also be patented to only cover the pattern 302 on the side wall. After the release layer is removed, the device 102 a, b, c will be connected to layer 104 through layer 112 connected in pattern 302. Here, after the microdevices are bonded to the receiver substrate, the layer 112 breaks and leaves the devices in the receiver substrate.

In another related embodiment shown in FIG. 2C, a release layer 402 is formed under the devices 102 a, b, c. Here, the release layer can be removed to prepare the device for the transfer.

In another related embodiment demonstrated in FIG. 2D, the anchor layer 404 is also formed under the device and the release layer 402 is formed between the bonding layer 104 and anchor layer 404.

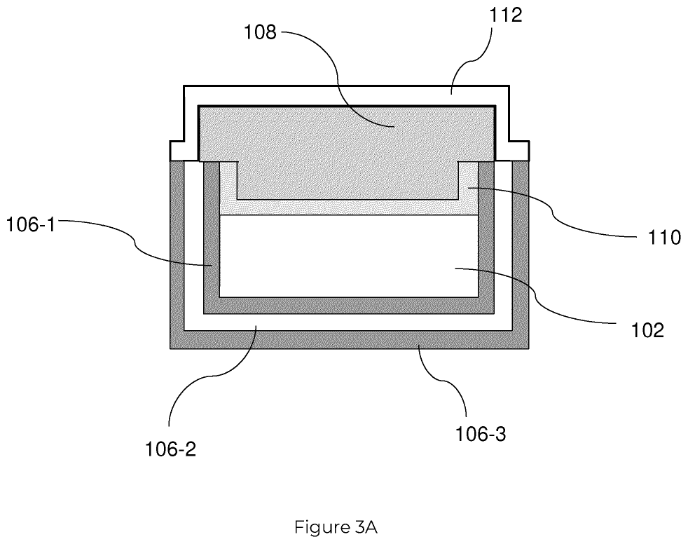

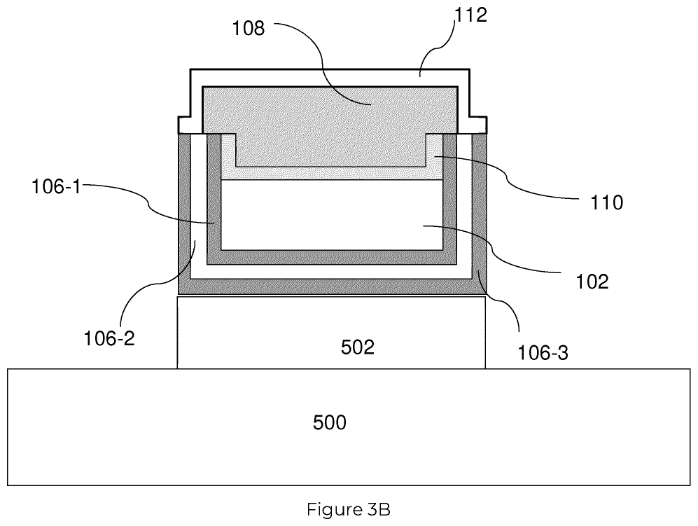

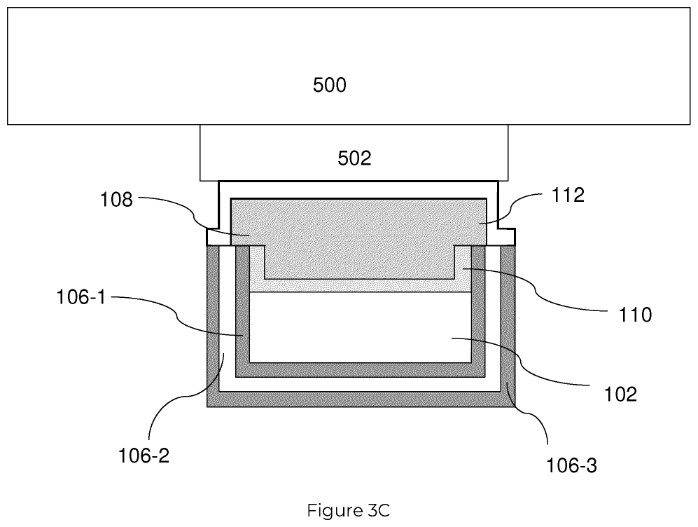

FIG. 3A shows an exemplary embodiment of microdevices developed with an optical layer integrated in the device. The device 102 is covered by a protection layer which has sub-layers 106-1, 106-2 and 106-3. The protection layer can include several sub-layers such as a dielectric layer (or high bandwidth material) 106-1 around the device 102. An optical layer that can be reflective 106-2 and another passivation layer 106-3. Part of protection layers can be extended taller than the device 102 height creating a housing for holding the optical layer 108. There can be an optical enhancement layer 110 between the optical layer 108 and device 102. An encapsulation/passivation layer 112 can be used to cover at least part of the optical layer 112 or the device 102 or other layers. The passivation layer 112 can include several sub layers such as anchor, optical enhancement, and others. The device can have pads on either the top side or bottom side. To form a pad layer at protection layer (106-1,2,3), the layers are patterned or formed around the pad to provide access to the microdevice 102. For forming a pad on the optical layer 108 side, the passivation layer 112, optical layer 108 and the optical enhancement layer 110 are patterned or formed around the pads.

FIG. 3B shows an example of integrating the device of FIG. 3A into a receiver backplane 500. The backplane can have pixel circuits, metal traces, and other circuitry layers. It has a landing area 502. The landing area can have pads that get connected to the pads of the device 102. In this example, the face of the device covered by a protection layer which has sub-layers (106-1,2,3) is connected to the backplane 500. If the pads are at this face, they can be bonded directly to the pads in landing area 502 of the backplane. The landing area can also have other layers to hold the device such as adhesive layers. If the pads of the device are on the other surface, other layers such as planarization, metalization, and VIA can be used to connect the device to the backplane. In another case, the backplane circuitry can be made after the device is integrated into the backplane 500. Here, the light input or output can pass through the optical layer. For example, in case of microLED, the light generated by device 102 is passed through the optical layer 108. The optical layer can be color conversion to convert the device 102 light to a different wavelength or it can be lens structure to confine the light or other type of optical function. In this case, layer 106-2 can reflect the light through the optical layer 108. In another related case, the light can go through the substrate (bottom emission). Here, there is no reflective layer in the protective layer and passivation layer 112 has a reflective layer.

FIG. 3C shows an example of integrating the device of FIG. 3A into a receiver backplane 500. The backplane can have pixel circuits, metal traces, and other circuitry layers. It has a landing area 502. The landing area can have pads that get connected to the pads of the device 102. In this example, the face of the device covered by optical 108 and passivation layer 112 is connected to the backplane 500. If the pads are at this face, they can be bonded directly to the pads in landing area 502 of the backplane. The landing area can also have other layers to hold the device such as adhesive layers. If the pads of the device are on the other surface, other layers such as planarization, metalization, and VIA can be used to connect the device to the backplane. In another case, the backplane circuitry can be made after the device is integrated into the backplane 500. Here, the light input or output can pass through the optical layer 108 and substrate 500 (bottom emission). For example, in case of microLED, the light generated by device 102 is passed through the optical layer 108. The optical layer can be color conversion to convert the device 102 light to a different wavelength or it can be lens structure to confine the light or other type of optical function. In this case, layer 106-2 can reflect the light through the optical layer 108. In another related case, the light can go through the protective layers (top emission). Here, there is no reflective layer in the protective layer and passivation layer 112 can have a reflective layer.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method of developing microdevices with an optical structure on a substrate, the method comprising:
holding a microdevice on top of a substrate wherein the microdevice has a top side, a bottom side and side walls that are different from the bottom side and the top side and the top side faces away from the substrate;
forming optical layers on the top side of microdevices;
forming a passivation layer on top of optical layers; and
transferring microdevices and the optical layers into a system substrate.

2. The method of claim 1, wherein a protection layer is deposited on the sidewalls and at least part of the bottom side of the microdevices.

3. The method of claim 2, wherein a first layer is covering an interface between microdevice and the protection layer.

4. The method of claim 1, wherein a second layer is covering a part of an interface between the optical layers and the microdevices.

5. The method of claim 1, wherein the substrate is either a donor substrate or a temporary substrate.

6. The method of claim 3, wherein the first layer is a polymer.

7. The method of claim 4, wherein the second layer is either another passivation layer, an anchor layer, a bridge layer, or a separate optical layer.

8. The method of claim 1, wherein the optical layers include color conversion layers.

9. The method of claim 1, wherein the optical layers include color filter layers.

10. The method of claim 1, wherein the optical layers comprise a lens structure.

11. The method of claim 1, wherein the optical layers are a combination of color conversion layers and a lens structure.

12. The method of claim 1, wherein the optical layers comprise of different optical layers formed by patterning.

13. The method of claim 1, wherein the passivation layer also includes an anchor layer.

14. The method of claim 13, wherein the anchor layer is patterned outside the microdevices.

15. The method of claim 1, wherein a release layer is formed and is patterned and aligned with the optical layers and the microdevices.

16. The method of claim 15, wherein the release layer is further patterned to fit the optical layers.

17. The method of claim 1, wherein the microdevices are etched back to create a housing structure for at least a part of the optical layers wherein the part of the optical layers is formed inside the housing structure.

18. The method of claim 16, wherein additional layers are formed on top of the optical layers, and a second substrate is bonded to a top surface using a bonding layer.

19. The method of claim 18, wherein the bonding layer is either an adhesive or a polymer.

20. The method of claim 18, wherein the substrate is a temporary substrate that is removed along with the first layer exposing an original bottom surface of the microdevices.

21. The method of claim 20, wherein the protection layer is removed or patterned.

22. The method of claim 20, wherein a part of the protection layer covers part of the microdevice, and a remaining part is reflective.

23. The method of claim 20, wherein the second layer or the passivation layer is patterned to form anchors, bridges, or membrane.

24. The method of claim 20, wherein the second layer or the passivation layer or the bonding layer is a temporary adhesive that releases the microdevices under different conditions wherein further the release layer is removed.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. The method of claim 1, wherein the devices are formed on the substrate.

54. The method of claim 53, wherein sidewalls of the microdevices are covered with different housing layers comprising dielectrics and or reflective layers.

55. The method of claim 54, wherein the top or bottom surface of the device is etched back to expose side walls forming a housing cavity on top or bottom surface.

56. The method of claim 55, wherein an optical layer is formed on the top or bottom surface and at least a part of the optical layer is inside the housing cavity formed by the housing layers.

57. The method of claim 56, wherein there are other layers before or after the optical layer.

58. The method of claim 55, wherein the etch back process includes patterning and leaves some of the device materials on the side walls and only etch back an inner part of top or bottom surfaces.

59. The method of claim 55, wherein the etch back process is done by a wet etching or a dry etching process and the housing layers are formed by different deposition processes such as PECVD, ALD, spin coating and printing.
